(19) United States
(12) Patent Application Publication
(10) Pub. No.: US 2025/0192741 A1
(43) Pub. Date: Jun. 12, 2025

(54) VOLTAGE GENERATION CIRCUIT AND AUDIO OUTPUT CIRCUIT

(71) Applicant: Panasonic Automotive Systems Co., Ltd., Kanagawa (JP)

(72) Inventor: Takahiro HAYAKAWA, Kanagawa (JP)

(21) Appl. No.: 19/057,502

(22) Filed: Feb. 19, 2025

Related U.S. Application Data
(63) Continuation of application No. PCT/JP2023/016985, filed on Apr. 28, 2023.

(30) Foreign Application Priority Data
Sep. 30, 2022 (JP) 2022-158437

(51) Int. Cl. H03F 3/45

(52) U.S. Cl. CPC H03F 3/45475; H03F 2200/03; H03F 2200/129

(57) ABSTRACT

A voltage generation circuit includes a voltage input terminal, a voltage output terminal, a first resistor having a first terminal electrically connected to the voltage input terminal, a second resistor having a third terminal electrically connected to the second terminal and a fourth terminal electrically connected to a ground potential, a first capacitor having a first capacitive terminal electrically connected to the voltage input terminal, a third resistor having a fifth terminal electrically connected to a second capacitive terminal, a fourth resistor having a seventh terminal electrically connected to a sixth terminal, and a first operational amplifier having a first inverting input terminal electrically connected to the sixth terminal, a first non-inverting input terminal electrically connected to the second terminal, and a first output terminal electrically connected to the voltage output terminal and an eighth terminal.

### TECHNICAL FIELD

The present disclosure relates to a voltage generation circuit and an audio output circuit.

### BACKGROUND ART

In the related art, there is known a preamplifier that performs amplification and level shift, as a voltage generation circuit for generating a predetermined voltage. This preamplifier is a preamplifier that amplifies, using an operational amplifier, an input signal input from a pair of input terminals and outputs the amplified signal, in which a negative input terminal of the pair of input terminals is connected to an inverting input terminal of the operational amplifier via a negative input resistor, the inverting input terminal and an output of the operational amplifier are connected by a feedback resistor, a positive input terminal is connected to a non-inverting input terminal of the operational amplifier via a positive input resistor, and a voltage division point obtained by resistively dividing a positive reference voltage is connected to the non-inverting input terminal of the operational amplifier (see Patent Literature 1).

### CITATION LIST

### Patent Literature

Patent Literature 1: JPH11-168330A

### SUMMARY OF INVENTION

In the voltage generation circuit in the related art, a voltage is generated in a state where a variation component superimposed on an input voltage is not sufficiently reduced, and further improvement is required.

The present disclosure provides a voltage generation circuit capable of generating a voltage by reducing a variation component superimposed on an input voltage and an audio output circuit.

An aspect of the present disclosure is a voltage generation circuit including: a voltage input terminal to which an input voltage is input; a voltage output terminal from which an output voltage is output; a first resistor having a first terminal and a second terminal, the first terminal being electrically connected to the voltage input terminal; a second resistor having a third terminal and a fourth terminal, the third terminal being electrically connected to the second terminal, and the fourth terminal being electrically connected to a ground potential; a first capacitor having a first capacitive terminal and a second capacitive terminal, the first capacitive terminal being electrically connected to the voltage input terminal; a third resistor having a fifth terminal and a sixth terminal, the fifth terminal being electrically connected to the second capacitive terminal; a fourth resistor having a seventh terminal and an eighth terminal, the seventh terminal being electrically connected to the sixth terminal; and a first operational amplifier having a first inverting input terminal, a first non-inverting input terminal, and a first output terminal, the first inverting input terminal being electrically connected to the sixth terminal, the first non-inverting input terminal being electrically connected to the second terminal, and the first output terminal being electrically connected to the voltage output terminal and the eighth terminal.

An aspect of the present disclosure is an audio output circuit including: the voltage generation circuit; and a fourth operational amplifier, in which the fourth operational amplifier has a first input terminal, a second input terminal, and a fourth output terminal, an output voltage output by the voltage generation circuit is input to the first input terminal, an audio input signal is input to the second input terminal, and an audio output signal based on the audio input signal is output from the fourth output terminal.

According to the present disclosure, a voltage can be generated by reducing a variation component superimposed on an input voltage.

### BRIEF DESCRIPTION OF DRAWINGS

FIG. 1 is a circuit diagram illustrating an example of an audio output circuit according to a first embodiment;

FIG. 2 is a circuit diagram illustrating an example of a voltage generation circuit according to the first embodiment;

FIG. 3 is a circuit diagram illustrating an example of a voltage generation circuit according to a second embodiment;

FIG. 4 is a circuit diagram illustrating a voltage generation circuit according to a comparative example;

FIG. 5 is a diagram illustrating input and output characteristics of variation components according to the second embodiment and the comparative example;

FIG. 6 is a circuit diagram illustrating an example of a voltage generation circuit according to a third embodiment;

FIG. 7 is a circuit diagram illustrating an example of a voltage generation circuit according to a fourth embodiment;

FIG. 8 is a circuit diagram illustrating an example of a voltage generation circuit according to a fifth embodiment;

FIG. 9 is a circuit diagram illustrating an example of a voltage generation circuit according to a sixth embodiment;

FIG. 10 illustrates an example of an output voltage of the voltage generation circuit in the second embodiment and an output voltage of a voltage generation circuit in the present embodiment;

FIG. 11 is a circuit diagram illustrating a voltage generation circuit according to a modification of the sixth embodiment;

FIG. 12 is a circuit diagram illustrating an example of a voltage generation circuit according to a seventh embodiment; and

FIG. 13 illustrates an example of an output voltage of the voltage generation circuit in the sixth embodiment and an output voltage of the voltage generation circuit in the present embodiment.

### DESCRIPTION OF EMBODIMENTS

### Findings as Basis of Present Disclosure

A voltage generation circuit in the related art may operate as a bias circuit that outputs a bias voltage. The bias circuit outputs a bias voltage based on an input voltage, but in a case where the input voltage varies, a bias voltage containing a variation component will be output. In order to remove the variation component, a method of absorbing the variation component by adding an element such as a capacitor to the bias circuit is conceivable. However, in this case, it is necessary to increase an electrostatic capacity of the capacitor, and thus the size of the capacitor increases, which leads to an increase in size of a device including the bias circuit. Therefore, there is a demand for a technique for reducing a variation component while suppressing an increase in size of the device.

Hereinafter, embodiments of a voltage generation circuit and an audio output circuit according to the present disclosure will be described with reference to the drawings.

### First Embodiment

### Configuration of Audio Output Circuit

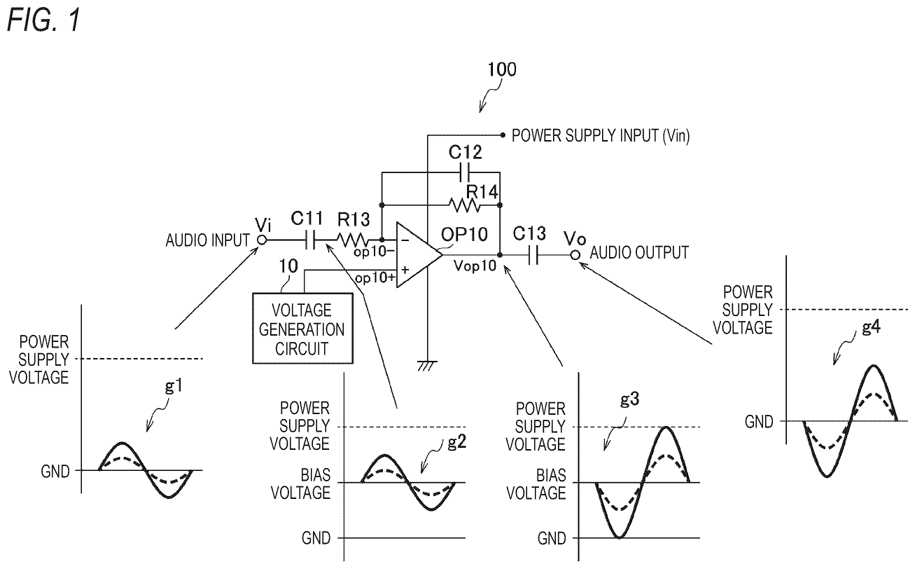

FIG. 1 is a circuit diagram illustrating an example of an audio output circuit 100 according to a first embodiment. The audio output circuit 100 is an audio signal amplifier circuit. The audio output circuit 100 includes an audio input terminal Vi, an audio output terminal Vo, an operational amplifier OP10, and a voltage generation circuit 10.

The operational amplifier OP10 includes an inverting input terminal op10−, a non-inverting input terminal op10+, and an output terminal Vop10. The inverting input terminal op10− is electrically connected to the audio input terminal Vi via a capacitor C11 and a resistor R13 which are connected in series. The inverting input terminal op10− is electrically connected to the output terminal Vop10 via a capacitor C12 and a resistor R14 which are connected in parallel. The non-inverting input terminal op10+ is connected to a voltage output terminal (not illustrated in FIG. 1) of the voltage generation circuit 10. A bias voltage generated by the voltage generation circuit 10 is input to the non-inverting input terminal op10+. The output terminal Vop 10 is electrically connected to the audio output terminal Vo via a capacitor C13. Each of the capacitor C11, the capacitor C12, and the capacitor C13 is, for example, a capacitor.

The audio output circuit 100 is an amplifier circuit with a single power supply, which is electrically connected to a power supply voltage and a ground potential, that is, ground. The audio output circuit 100 amplifies an amplitude of the audio input signal by a factor of 2, for example, and outputs the amplified audio output signal as an audio output signal. The audio output circuit 100 may be used in, for example, car audio.

In FIG. 1, a graph g1 illustrates a voltage amplitude waveform of the audio input signal at the audio input terminal Vi. In the graph g1, a solid line indicates a waveform when the amplitude of the audio input signal is maximum, and a broken line indicates an example of a waveform when the amplitude of the audio input signal is smaller than the maximum. Here, the amplitude of the audio input signal when the amplitude is maximum is the maximum amplitude at which the operational amplifier OP10 can output an audio without distorting the audio input signal. A relation between the waveform indicated by the solid line and the waveform indicated by the broken line is the same for a graph g2, a graph g3, and a graph g4.

The graph g2 is a diagram illustrating a voltage amplitude waveform of an input signal between the capacitor C11 and the resistor R13. In the graph g2, a bias voltage is added to a signal from the audio input terminal Vi in either waveform. The bias voltage is a voltage generated and output by the voltage generation circuit 10, and is, for example, a voltage that is half (½) of the power supply voltage.

The graph g3 is a diagram illustrating a voltage amplitude waveform of an output signal at the output terminal Vop10 of the operational amplifier OP10. In the waveform illustrated in the graph g3, phases of the waveforms illustrated in the graph g2 are inverted, and the amplitude is amplified at a predetermined amplification factor. The amplification factor is, for example, twice.

The graph g4 is a diagram illustrating a voltage amplitude waveform of the audio output signal at the audio output terminal Vo. In the audio output signal illustrated in the graph g4, the bias voltage is removed by an operation of the capacitor C13.

Therefore, when a noise component is superimposed on the bias voltage as an output voltage output from the voltage generation circuit, the operational amplifier OP10 adds the noise component to amplify the input signal. For this reason, it is preferable that a constant voltage which does not include a noise component is obtained as the bias voltage. Accordingly, the operational amplifier OP10 can amplify the input signal and output the amplified input signal without the noise component being superimposed. In this case, it is possible to secure a signal having a large amplitude by amplification processing of the operational amplifier OP10. The noise component is an AC component other than a DC component of the voltage, and is a variation component of the voltage.

The bias voltage may not be a value which is half of the power supply voltage. For example, the bias voltage may be adjusted to a voltage other than half of the power supply voltage depending on IC constituting the operational amplifier OP10.

The voltage generation circuit 10 may have various circuit configurations. Hereinafter, the circuit configurations of the voltage generation circuit 10 will be described for each embodiment. The voltage generation circuit 10 according to the first embodiment is a voltage generation circuit 10A. The voltage generation circuit 10 according to a second embodiment is a voltage generation circuit 10B. The voltage generation circuit 10 according to a third embodiment is a voltage generation circuit 10C. The voltage generation circuit 10 according to a fourth embodiment is a voltage generation circuit 10D. The voltage generation circuit 10 according to a fifth embodiment is a voltage generation circuit 10E. The configuration of the audio output circuit 100 is the same in each embodiment.

### Configuration of Voltage Generation Circuit

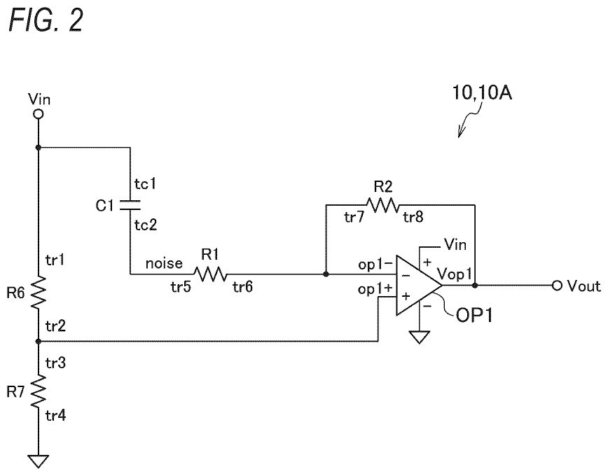

FIG. 2 is a circuit diagram illustrating an example of the voltage generation circuit 10A. The voltage generation circuit 10A includes a voltage input terminal Vin, a voltage output terminal Vout, a resistor R1, a resistor R2, a resistor R6, a resistor R7, a capacitor C1, and an operational amplifier OP1.

An input voltage is input to the voltage input terminal Vin. An output voltage is output from the voltage output terminal Vout. The resistor R6 has a terminal tr1 and a terminal tr2. The terminal tr1 is electrically connected to the voltage input terminal Vin. Here, “electrically connected” includes a case where two elements are directly connected to each other and a case where a current flows from one element to the other element with another conductive element interposed therebetween. The resistor R7 has a terminal tr3 and a terminal tr4. The terminal tr3 is electrically connected to the terminal tr2. The terminal tr4 is electrically connected to the ground potential, that is, the ground. The capacitor C1 has a capacitive terminal tc1 and a capacitive terminal tc2. Hereinafter, a terminal of a capacitor may be referred to as a capacitive terminal. The capacitive terminal tc1 is electrically connected to the voltage input terminal Vin and the terminal tr1. The resistor R1 has a terminal tr5 and a terminal tr6. The terminal tr5 is electrically connected to the capacitive terminal tc2. The terminal tr5 may be directly connected to the capacitive terminal tc2. The resistor R2 has a terminal tr7 and a terminal tr8. The terminal tr7 is electrically connected to the terminal tr6.

The operational amplifier OP1 has an inverting input terminal op1−, a non-inverting input terminal op1+, and an output terminal Vop1. The inverting input terminal op1− is electrically connected to the terminal tr6 and the terminal tr7. The non-inverting input terminal op1+ is electrically connected to the terminal tr2 and the terminal tr3. The output terminal Vop1 is electrically connected to the voltage output terminal Vout and the terminal tr8. The operational amplifier OP1 includes a positive-side power supply terminal and a negative-side power supply terminal. The positive-side power supply terminal is electrically connected to a power supply potential, and the negative-side power supply terminal is electrically connected to the ground potential. That is, the voltage generation circuit 10A is a circuit with a single power supply. For example, a voltage same as the input voltage input to the voltage input terminal Vin is input to the positive-side power supply terminal. The voltage input to the positive-side power supply terminal may be different from the input voltage input to the voltage input terminal Vin.

A resistance value of the resistor R6 is, for example, 10 kΩ. A resistance value of the resistor R7 is, for example, 10 kΩ. A capacitance value of the capacitor C1 is, for example, 1 μF. A resistance value of the resistor R1 is, for example, 30 kΩ. A resistance value of the resistor R2 is, for example, 30 kΩ. The capacitance value of each element is, for example, a value of electrostatic capacity.

The input voltage input from the voltage input terminal Vin is divided by the resistor R6 and the resistor R7, and is input to the non-inverting input terminal op1+. The input voltage may include a DC component which is an original input voltage and a variation component which is noise. In the present embodiment, the resistance value of the resistor R6 is equal to the resistance value of the resistor R7. Therefore, the input voltage is input to the non-inverting input terminal op1+ as a voltage approximately half of the magnitude. At this time, both the DC component and the variation component included in the input voltage are approximately halved and input to the non-inverting input terminal op1+. An amplitude of the variation component input to the non-inverting input terminal op1+ is multiplied by (1+(resistance value of resistor R2)/(resistance value of resistor R1)), and is output to the output terminal Vop1. At this time, the phase is not inverted between the variation component input to the non-inverting input terminal op1+ and the variation component output to the output terminal Vop1. In the present embodiment, the resistance value of the resistor R1 is equal to the resistance value of the resistor R2. Therefore, the variation component input to the non-inverting input terminal op1+ is output to the output terminal Vop1 with the phase not being changed and the amplitude being multiplied by twice. That is, a variation component having the same amplitude as the variation component included in the input voltage is output to the output terminal Vop1. The input voltage input from the voltage input terminal Vin is input to the inverting input terminal op1− via the capacitor C1 and the resistor R1. The capacitor C1 blocks the DC component of the input voltage to extract the variation component from the input voltage. The variation component input to the resistor R1 is output to the output terminal Vop1 with the phase being inverted and the amplitude being multiplied by (resistance value of resistor R2)/(resistance value of resistor R1). In the present embodiment, the resistance value of the resistor R1 is equal to the resistance value of the resistor R2. Therefore, the variation component input to the resistor R1 is output to the output terminal Vop1 with the phase being inverted and the amplitude being multiplied by once. Accordingly, since the voltage generation circuit 10A can cancel the variation component input to the non-inverting input terminal op1+, it is possible to reduce the variation component included in the output voltage output from the voltage output terminal Vout.

For example, the following noise may be considered as the noise as the variation component. The noise may include noise generated by a microcomputer, a DSP, or another device that is electrically connected to the voltage input terminal Vin. The noise may include electrical noise generated by a drive system of a vehicle on which the voltage generation circuit 10 and the audio output circuit 100 are mounted. For example, the noise may include noise of an alternator, a motor, or an ignition of the vehicle. The noise may include electrical noise derived from outside the vehicle. The noise may also include noise generated by the audio output circuit 100.

With the voltage generation circuit 10, the variation component that may be included in the input voltage input to the voltage input terminal Vin is extracted by the capacitor C1 and is applied to the inverting input terminal op1−, and the signal output from the operational amplifier OP1 is fed back. Accordingly, the voltage generation circuit 10 can cancel the variation component, and can output a constant voltage even when the input voltage varies. In addition, the voltage generation circuit 10 can remove the variation component with a small component, as compared with a case where the variation component is suppressed by a filter. In addition, the voltage generation circuit 10 does not remove the variation component by using a diode such as a Zener diode. Therefore, it is possible to suppress occurrence of noise caused by an element in the voltage generation circuit 10, which may occur when, for example, a diode is used. A ratio of the resistance value of the resistor R6 to the resistance value of the resistor R7 is equal to a ratio of the resistance value of the resistor R1 to the resistance value of the resistor R2. Accordingly, the output voltage of the operational amplifier OP1 is less likely to vary.

In addition, the voltage generation circuit 10A can remove a variation component in a wider frequency band as compared with a case where the voltage generation circuit 10B according to the second embodiment to be described later includes a capacitor C2.

In addition, the audio output circuit 100 including the voltage generation circuit 10 can use a constant voltage with suppressed variation component as the bias voltage. Accordingly, the audio output circuit 100 can amplify the audio input signal and output the amplified audio input signal without the variation component being superimposed. Therefore, the audio output circuit 100 can output an audio output signal with suppressed noise.

### Second Embodiment

### Configuration of Voltage Generation Circuit

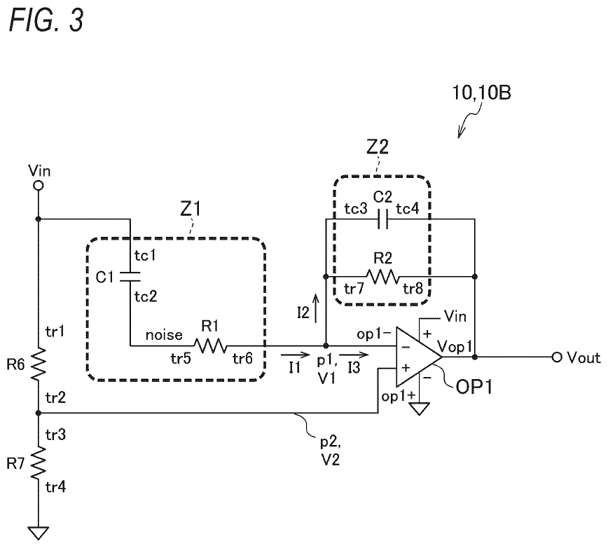

FIG. 3 is a circuit diagram illustrating an example of the voltage generation circuit 10B according to the second embodiment. The voltage generation circuit 10B is different from the voltage generation circuit 10A in that the voltage generation circuit 10B includes the capacitor C2. Regarding configurations and operations of the voltage generation circuit 10B same as those of the voltage generation circuit 10A according to the first embodiment, the description thereof will be omitted or simplified.

The voltage generation circuit 10B includes the capacitor C2 in addition to the configuration of the voltage generation circuit 10A. The capacitor C2 has a capacitive terminal tc3 and a capacitive terminal tc4. The capacitive terminal tc3 is electrically connected to the terminal tr7. The capacitive terminal tc3 may be directly connected to the terminal tr7. The capacitive terminal tc4 is electrically connected to the terminal tr8 and the output terminal Vop1 of the operational amplifier OP1. The capacitive terminal tc4 may be directly connected to the terminal tr8 and the output terminal Vop1. The capacitor C2 is connected in parallel with the resistor R2.

A capacitance value of the capacitor C2 is 0.47 pF, for example.

The capacitor C2 adjusts a phase of a high-frequency component passing through the capacitor C2. Therefore, the capacitor C2 can improve phase lag in a feedback circuit fed back from the output terminal Vop1 to the inverting input terminal op1−, and thus contributes to suppression of oscillation of the operational amplifier OP10 in a high frequency band. (Relation between Input Voltage and Output Voltage)

Next, a relation between the input voltage input from the voltage input terminal Vin and the output voltage output from the voltage output terminal Vout will be described.

In the following description, resistance values of resistors (R1, R2, . . . ) may be described using same reference numerals as those assigned to the resistors. Similarly, capacitance values of capacitors (C1, C2, . . . ) may be described using same reference numerals as those assigned to the capacitors. A value of the input voltage input from the voltage input terminal Vin may be described using the same reference numeral as the voltage input terminal Vin. Similarly, a value of the output voltage output from the voltage output terminal Vout may be described using the same reference numeral as the voltage output terminal Vout.

As illustrated in FIG. 3, the capacitor C1 and the resistor R1 connected in series form an impedance Z1. The capacitor C2 and the resistor R2 connected in parallel form an impedance Z2. Hereinafter, an impedance value of each impedance (Z1, Z2) may be described using the same reference numeral as the reference numeral assigned to the impedance.

First, a voltage V1 at a point p1 is represented by the following Equation (1) and Equation (2). “·” indicates a multiplication sign. The point p1 is a node to which the terminal tr6, the inverting input terminal op1−, and the terminal tr7 are connected. The voltage V1 represents a voltage input to the inverting input terminal op1−.

$$V 1 = Vin - I 1 \cdot Z 1 \qquad ( 1 )$$

$$V 1 = Vout + I 2 \cdot Z 2 \qquad ( 2 )$$

I1 is a current flowing from the resistor R1 to the point p1. I2 is a current flowing from the point p1 to the resistor R2 and the capacitor C2.

A voltage V2 at a point p2 is represented by the following equation. The point p2 is a node to which the terminal tr2, the terminal tr3, and the non-inverting input terminal op1+ are connected. The voltage V2 represents a voltage input to the non-inverting input terminal op1+.

$$[ Math . 1 ]$$

$$V 2 = \frac{R 7}{R 6 + R 7} \cdot Vin \qquad ( 3 )$$

Here, the operational amplifier OP1 operates so that the voltage V1 and the voltage V2 become the same voltage. Therefore, the following relational equation holds.

$$V 1 = V 2 \qquad ( 4 )$$

In a case where the current I1 is solved based on Equation (1) and Equation (4), the following relational equation holds.

$$[ Math . 2 ]$$

$$I 1 = \frac{( 1 - \frac{R 7}{R 6 + R 7} )}{Z 1} \cdot Vin \qquad ( 5 )$$

According to the Kirchhoff's law, the current flowing through the point p1 is as follows.

$$I 1 = I 2 + I 3$$

I3 is a current flowing from the point p1 to the inverting input terminal op1−.

An input impedance of the inverting input terminal op1− is very high. Therefore, the current I3 has a current amount which is almost negligible. Therefore, the following relational equation holds.

$$I 1 = I 2 \qquad ( 6 )$$

In a case where the output voltage Vout is solved based on Equation (2), Equation (3), Equation (4), Equation (5), and Equation (6), the following is obtained.

$$[ Math . 3 ]$$

$$Vout = ( \frac{R 7}{R 6 + R 7} - \frac{R 6}{R 6 + R 7} \cdot \frac{Z 2}{Z 1} ) \cdot Vin \qquad ( 7 )$$

Next, an operation on the DC component and the variation component of the input voltage will be described.

First, in order to simplify Equation (7), R6=R7 is set, and Equation (7) is modified to obtain Equation (8).

$$[ Math . 4 ]$$

$$Vout = \frac{1}{2} \cdot ( 1 - \frac{Z 2}{Z 1} ) \cdot Vin \qquad ( 8 )$$

The impedance Z1 and the impedance Z2 are expressed in complex numbers.

The impedance Z1 is a combined series resistance of the capacitor C1 and the resistor R1, and thus the following relational equation holds.

$$[ Math . 5 ]$$

$$Z 1 = R 1 + \frac{1}{j ω C 1}$$

Here, when modification is performed by substituting ω=2πf, the following relational equation holds. A frequency f is the frequency of the variation component included in the input voltage.

$$[ Math . 6 ]$$

$$Z 1 = R 1 - j \frac{1}{2 π fC 1} \qquad ( 9 )$$

Here, in a case where the frequency f at which a real part and an imaginary part of Equation (9) are equal is a cutoff frequency flow, the following relational equation holds.

$$[ Math . 7 ]$$

$$R 1 = \frac{1}{2 π {f}_{low} C 1}$$

$${f}_{low} = \frac{1}{2 π C 1 R 1}$$

When the frequency f is lower than the cutoff frequency flow, the impedance Z1 increases. When f=0, that is, when the input voltage includes only the DC component, the impedance Z1 becomes infinity value. Regarding the DC component included in the input voltage Vin, the following relational equation holds when an infinity is substituted for the impedance Z1 in Equation (8).

$$[ Math . 8 ]$$

$$Vout = \frac{1}{2} \cdot ( 1 - \frac{Z 2}{∞} ) \cdot Vin = \frac{1}{2} \cdot Vin$$

In this manner, the output voltage Vout is a value of ½ of the input voltage Vin.

The impedance Z2 is a combined parallel resistance of the capacitor C2 and the resistor R2, and thus the following relational equation holds.

$$[ Math . 9 ]$$

$$\frac{1}{Z 2} = \frac{1}{R 2} + j ω C 2$$

Further, when modification is performed by substituting ω=2πf, the following relational equation holds.

$$[ Math . 10 ]$$

$$\frac{1}{Z 2} = \frac{1}{R 2} + j 2 π fC 2 \qquad ( 10 )$$

In a case where the frequency f at which a real part and an imaginary part of Equation (10) are equal is a cutoff frequency f_{high}, the following relational equation holds.

$$\begin{matrix}[ Math . 11 ] & \\ \frac{1}{R 2} = 2 π {f}_{h i g h} C 2 {f}_{h i g h} = \frac{1}{2 π C 2 R 2} & \end{matrix}$$

When the frequency f is higher than the cutoff frequency f_{high}, a value of a reciprocal of the impedance Z2, in other words, 1/Z2, increases. A value of a reciprocal of the impedance Z2 is referred to as admittance. That is, when f=infinity, the value of the impedance Z2 is 0. Regarding the high-frequency component included in the input voltage Vin, when 0 is substituted into the impedance Z2 of Equation (9), the following relational equation holds.

$$\begin{matrix}[ Math . 12 ] & \\ Vout = \frac{1}{2} \cdot ( 1 - \frac{0}{Z 1} ) \cdot Vin = \frac{1}{2} \cdot Vin & \end{matrix}$$

In this manner, the output voltage Vout is a value of ½ of the input voltage Vin.

On the other hand, when the frequency f is between the cutoff frequency flow and the cutoff frequency f_{high} and Z1=Z2, a value in the parentheses of Equation (8) becomes “0”, and the output voltage Vout becomes 0. That is, in this case, the variation component of the input voltage Vin is not output to the output voltage Vout and is removed.

In a case where the frequency f at which Z1=Z2 is obtained, the following relational equation holds based on Equation (9) and Equation (10).

$$\begin{matrix}[ Math . 13 ] & \\ R 1 - j \frac{1}{2 π fC 1} = \frac{1}{\frac{1}{R 2} + j 2 fC 21} & ( 11 )\end{matrix}$$

When Equation (11) is modified, the following relational equation holds.

$$\begin{matrix}[ Math . 14 ] & \\ \frac{R 1}{R 2} - j \frac{1}{2 π fC 1 R 2} + j 2 π f C 2 R 1 - \frac{C 2}{C 1} = 1 & ( 12 )\end{matrix}$$

Here, when R2=R1 and C1 >>C2, a first term on a left side is “1” and a fourth term can be approximated to “0”. Therefore, Equation (12) is as follows.

$$\begin{matrix}[ Math . 15 ] & \\ j ( 2 π fC 2 R 2 - \frac{1}{2 π fC 1 R 1} ) = 0 & ( 13 )\end{matrix}$$

In a case where the frequency f is solved based on Equation (13), the following relational equation holds.

$$\begin{matrix}[ Math . 16 ] & \\ f = \frac{1}{2 π \sqrt{C 1 C 2 R 1 R 2}} & ( 14 )\end{matrix}$$

In the case of the frequency f represented by Equation (14), the effect of removing the variation component by the voltage generation circuit 10B is the highest.

The cutoff frequency f_{low} may be, for example, 5 Hz or more and 10 Hz or less. The cutoff frequency f_{high} may be, for example, 500 kHz or more and 10 MHz or less, and may be 10 MHz or more. In this case, the voltage generation circuit 10B may suitably remove the variation component of the input voltage in a frequency range of 20 Hz to 20 kHz or a frequency range of 20 Hz to 100 kHz.

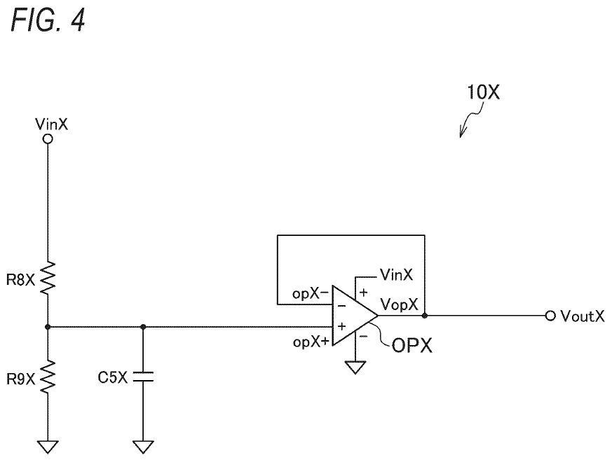

FIG. 4 is a circuit diagram illustrating a voltage generation circuit 10X according to a comparative example. The voltage generation circuit 10X includes a resistor R8X, a resistor R9X, a capacitor C5X, an operational amplifier OPX, a voltage input terminal VinX, and a voltage output terminal VoutX.

One end of the resistor R8X is electrically connected to the voltage input terminal VinX. One end of the resistor R9X is electrically connected to the other end of the resistor R8X, and the other end of the resistor R9X is electrically connected to the ground potential. One end of the capacitor C5X is electrically connected to the other end of the resistor R8X and the one end of the resistor R9X, and the other end of the capacitor C5X is electrically connected to the ground potential.

An inverting input terminal opX− of the operational amplifier OPX is electrically connected to an output terminal thereof. A non-inverting input terminal opX+ of the operational amplifier OPX is electrically connected to the other end of the resistor R8X, the one end of the resistor R9X, and the one end of the capacitor C5X. An output terminal VopX of the operational amplifier OPX is electrically connected to the inverting input terminal opX− thereof and the voltage output terminal VoutX.

A resistance value of the resistor R8X is, for example, 10 kΩ. A resistance value of the resistor R9X is, for example, 10 kΩ. A capacitance value of the capacitor C5X is, for example, 1 μF.

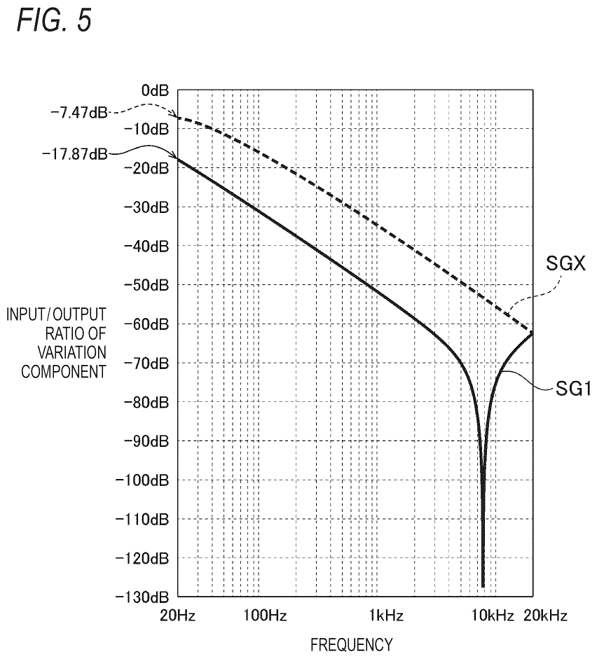

FIG. 5 is a diagram illustrating input and output characteristics of variation components as noise components according to the second embodiment and the comparative example. Specifically, FIG. 5 illustrates a change in magnitude of a variation component appearing at the voltage output terminal Vout when a sine wave is applied to the voltage input terminal as the variation component and the sine wave is swept in a range of 20 Hz to 20 kHz. 20 Hz to 20 kHz corresponds to a general audible frequency range. In FIG. 5, a noise signal SG1 indicating the variation component of the present embodiment is indicated by a solid line, and a noise signal SGX indicating the variation component of the comparative example is indicated by a broken line. In FIG. 5, the noise signal SG1 and the noise signal SGX are indicated by relative values (dB) indicating an output to an input, that is, relative values indicating the variation component included in the output voltage with respect to the variation component included in the input voltage.

Comparing the noise signal SG1 of the present embodiment with the noise signal SGX of the comparative example in the audible frequency range, it can be understood that the noise signal SG1 is smaller than the noise signal SGX over the entire audible frequency range, and noise is further reduced. For example, in the vicinity of 20 Hz, the noise can be further reduced by about 10 dB in the present embodiment than in the comparative example.

Therefore, it can be understood that the noise on an input side is less likely to be transmitted to an output side in the present embodiment than in the comparative example. Furthermore, it can be understood that in the present embodiment, there is a frequency (for example, about 8 kHz) at which input noise is greatly reduced. This frequency corresponds to the frequency f derived by Equation (14). In the present embodiment, it is possible to reduce a variation component between a low frequency that is determined by the capacitor C1 and a high frequency that depends on the operational performance of the operational amplifier OP1.

The voltage generation circuit 10B may adjust inclination of the graph illustrated in FIG. 5 by adjusting the capacitance value C1 and the resistance value R1. Therefore, in the voltage generation circuit 10B, it is possible to adjust a reduction function of the variation component, that is, an intensity and a frequency range of a noise cancellation function.

In addition, although the input and output characteristics of the variation components are not particularly illustrated in a graph in the first embodiment, the same applies to the first embodiment.

### First Modification of Second Embodiment

In the second embodiment, the resistance value R1 is equal to the resistance value R2, and the resistance value R6 is equal to the resistance value R7, but the present invention is not limited thereto. In the first modification, it suffices as long as resistance value R6:resistance value R7=resistance value R1:resistance value R2 is satisfied, but the resistance value R1 may be different from the resistance value R2, and the resistance value R6 may be different from the resistance value R7. In this case, the output voltage Vout satisfies the following relational equation.

$$\begin{matrix}[ Math . 17 ] & \\ Vout = \frac{R 7}{R 6 + R 7} \cdot Vin & \end{matrix}$$

The voltage generation circuit 10B may freely change the output voltage output from the voltage output terminal Vout by satisfying this relational equation. In this case, the voltage generation circuit 10B may also reduce a variation component as a noise component. In the present modification, as an example, a resistance value of the resistor R6 is 16.667 kΩ, and a resistance value of the resistor R7 is 10 kΩ. In addition, as an example, a resistance value of the resistor R1 is 30 kΩ, and a resistance value of the resistor R2 is 18 kΩ.

Hereafter, a processing for changing the output voltage Vout to any desired voltage will be explained.

In the voltage generation circuit 10, a DC component of the output voltage Vout can be set to any value other than ½ of a DC component of the input voltage Vin by changing a ratio of the resistance values of the resistor R6 and the resistor R7. In this case, it is necessary to adjust the resistance value R1 and the resistance value R2 in order to remove an AC component among the cutoff frequencies f_{low} to f_{high}.

When the input voltage Vin is only a DC component, the impedance Z1 becomes infinity value, and when impedance Z1=infinity is substituted into Equation (7), the following relational equation holds between the resistance value R6 and the resistance value R7.

$$\begin{matrix}[ Math . 18 ] & \\ R 6 = ( \frac{Vin - Vout}{Vout} ) \cdot R 7 & ( 15 )\end{matrix}$$

It is possible to determine the resistance value R6, using Equation (15), by determining the resistance value R7 and the output voltage Vout.

At this time, when constants of the impedance Z1 and the impedance Z2 are determined such that the value in the parentheses in Equation (7) is “0”, the AC component among the cutoff frequencies f_{low} to f_{high} can be removed without being output to the output voltage Vout. That is, the relation among the resistance value R6, the resistance value R7, the impedance Z1, and the impedance Z2 when the value in the parentheses in Equation (7) is “0”may be obtained. Specifically, the relation of the following Equation (16) may be established.

$$\begin{matrix}[ Math . 19 ] & \\ \frac{R 7}{R 6} = \frac{Z 2}{Z 1} & ( 16 )\end{matrix}$$

The capacitance value C1 and the capacitance value C2 are small, and thus can be ignored. Therefore, it can be approximated by using the relation of Equation (17).

$$\begin{matrix}[ Math . 20 ] & \\ \frac{R 7}{R 6} = \frac{R 2}{R 1} & ( 17 )\end{matrix}$$

In this manner, in the voltage generation circuit 10B, the generated bias voltage can be adjusted to any value by adjusting the resistance value of each resistor. In addition, by setting resistance value R6:resistance value R7=resistance value R1:resistance value R2 in the voltage generation circuit 10B, it is possible to output any output voltage within a range in which the operational amplifier OP1 is operable while maintaining the noise cancellation capability.

### Second Modification of Second Embodiment

In the second embodiment, it is mainly exemplified that in the voltage generation circuit 10B, the operational amplifier OP1 is with a single power supply and a negative-side power supply terminal is connected to a ground potential, but the present invention is not limited thereto. The voltage generation circuit 10B may operate even when the operational amplifiers OP1 of dual power supplies are provided. As an example, a sum of a DC component of 8 V and a variation component may be applied to a positive-side power supply terminal (Vin) of the operational amplifier OP1. In addition, a DC component of −8 V may be applied to a negative-side power supply terminal of the operational amplifier OP1.

### Third Modification of Second Embodiment

In the second embodiment, it is mainly exemplified that in the voltage generation circuit 10B, the operational amplifier OP1 is with a single power supply and a negative-side power supply terminal is connected to a ground potential, but the present invention is not limited thereto. A positive-side power supply terminal of the operational amplifier OP1 may be connected to a ground potential, and a negative-side power supply terminal thereof may be connected to a predetermined potential. In other words, the voltage generation circuit 10B may operate even when the operational amplifier OP1 with a positive single power supply is provided, and the voltage generation circuit 10B may operate even when the operational amplifier OP1 with a negative single power supply is provided.

The voltage generation circuit 10B according to the second embodiment includes the capacitor C2 as compared with the first embodiment, so that oscillation of the operational amplifier OP1 can be suppressed. Effects other than this point are the same as those of the first embodiment. Therefore, a relation between an input voltage and an output voltage described above and a comparison result of FIG. 5 can be similarly applied to the first embodiment.

### Third Embodiment

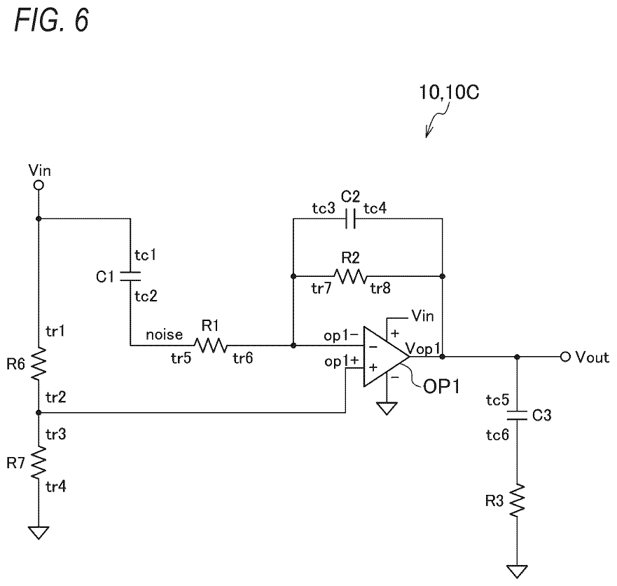

FIG. 6 is a circuit diagram illustrating an example of the voltage generation circuit 10C according to the third embodiment. The voltage generation circuit 10C is different from the voltage generation circuit 10B in that the voltage generation circuit 10C includes a capacitor C3. Regarding configurations of the voltage generation circuit 10C same as those of the voltage generation circuit 10A according to the first embodiment or the voltage generation circuit 10B according to the second embodiment, the description thereof will be omitted or simplified.

The voltage generation circuit 10C includes the capacitor C3 in addition to the configuration of the voltage generation circuit 10B. The capacitor C3 has a capacitive terminal tc5 and a capacitive terminal tc6. The capacitive terminal tc5 is electrically connected to the output terminal Vop1 and the voltage output terminal Vout. The capacitive terminal tc5 may be directly connected to the output terminal Vop1 and the voltage output terminal Vout. The capacitive terminal tc6 is electrically connected to a ground potential. The resistor R3 may be connected in series to the capacitive terminal tc6. The resistor R3 is, for example, an equivalent series resistance of the capacitor C3. A magnitude of a resistance value of the resistor R3 can be appropriately set based on characteristics of the capacitor C3.

A capacitance value of the capacitor C3 is, for example, 1 μF. The resistance value of the resistor R3 is, for example, 1 Ω.

The capacitor C3 can allow a variation component of a high frequency band of a signal output from the output terminal Vop1 to pass, but does not allow a DC component to pass. Accordingly, the capacitor C3 operates as a noise filter in an output stage of the voltage generation circuit 10C. Accordingly, an output voltage output from the voltage output terminal Vout is obtained by reducing the variation component in the high frequency band. In this manner, the voltage generation circuit 10C includes the capacitor C3 in a preceding stage of the voltage output terminal Vout, thereby improving an output characteristic of the high frequency band. The voltage generation circuit 10C can reduce a variation component in a band of a frequency of, for example, 100 kHz or more. Accordingly, the audio output circuit 100 including the voltage generation circuit 10C is easily compliant with electromagnetic compatibility (EMC) which is an international standard.

### Fourth Embodiment

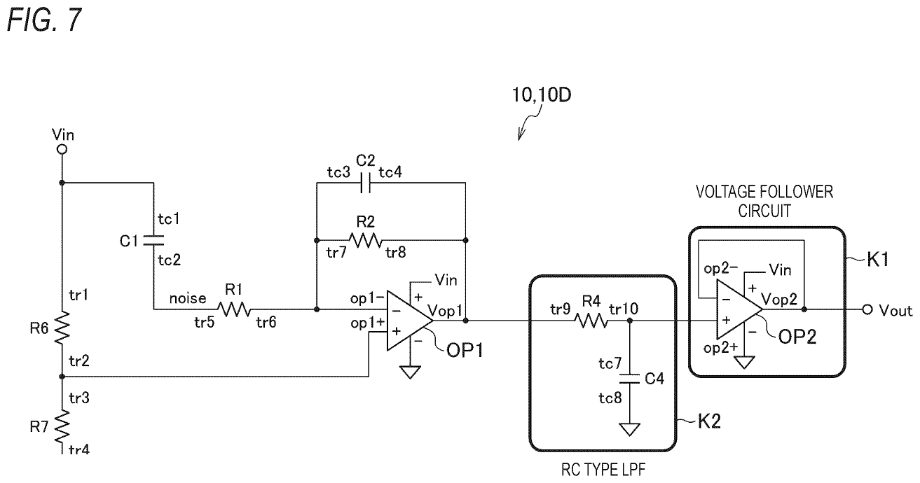

FIG. 7 is a circuit diagram illustrating an example of the voltage generation circuit 10D according to the fourth embodiment. Regarding configurations of the voltage generation circuit 10D same as those of the voltage generation circuit 10A according to the first embodiment, the voltage generation circuit 10B according to the second embodiment, or the voltage generation circuit 10C according to the third embodiment, the description thereof will be omitted or simplified.

The voltage generation circuit 10D includes a voltage follower circuit K1 and a low pass filter (LPF) circuit K2 which is an RC type LPF circuit in addition to the configuration of the voltage generation circuit 10B. The voltage follower circuit K1 includes an operational amplifier OP2. The LPF circuit K2 includes a resistor R4 and a capacitor C4.

The resistor R4 has a terminal tr9 and a terminal tr10. The terminal tr9 is electrically connected to the output terminal Vop1. The capacitor C4 has a capacitive terminal tc7 and a capacitive terminal tc8. The capacitive terminal tc7 is electrically connected to the terminal tr10 of the resistor R4. The capacitive terminal tc8 is electrically connected to a ground potential.

The operational amplifier OP2 has an inverting input terminal op2−, a non-inverting input terminal op2+, and an output terminal Vop2. The inverting input terminal op2− is electrically connected to the output terminal Vop2. The non-inverting input terminal op2+ is electrically connected to the terminal tr10 and the capacitive terminal tc7. The output terminal Vop2 is electrically connected to the voltage output terminal Vout.

A resistance value of the resistor R4 is, for example, 10 kΩ. A capacitance value of the capacitor C4 is, for example, 10 μF.

The voltage generation circuit 10D according to the present embodiment has a higher noise cancellation capability than the voltage generation circuit 10C according to the third embodiment. As an example, a case where the resistance value of the resistor R4 is 10 kΩ and the capacitance value of the capacitor C4 is 10 μF will be described. Of output voltages flowing into the LPF circuit K2, a variation component of a frequency higher than a cutoff frequency passes through the capacitor C4 and flows to the ground. In the present embodiment, the cutoff frequency is calculated as 1.59 Hz. Therefore, among output voltages output from the operational amplifier OP1 and input to the LPF circuit K2, a DC component of 1.59 Hz or less and a variation component are output to the voltage follower circuit K1, and an AC component of a frequency higher than 1.59 Hz is not output to the voltage follower circuit K1.

In a case where a load variation occurs, a current flowing through the resistor R4 varies, and noise derived therefrom may be generated.

For example, when an output impedance of the circuit is large, in a case where a load variation occurs and the output current changes, a voltage drop may occur and the output voltage may vary. On the other hand, even when a load variation occurs, the operational amplifier OP2 can maintain the voltage at the output terminal Vop2 constant based on feedback. Accordingly, the operational amplifier OP2 can operate in the same manner as when the output impedance is small. For example, even when a load variation occurs by a current flowing through the resistor R4, the voltage at the output terminal Vop2 can be maintained constant. Accordingly, the voltage at the voltage output terminal Vout electrically connected to the output terminal Vop2 is also maintained constant. Therefore, the voltage follower circuit K1 can reduce the output impedance of the voltage generation circuit 10D. When the voltage generation circuit 10D does not include the voltage follower circuit K1, the resistance value of the resistor R4 corresponds to the output impedance of the voltage generation circuit 10D. For example, when the voltage follower circuit K1 is not provided, the output impedance of the voltage generation circuit 10D is 10 kΩ. On the other hand, when the voltage follower circuit K1 is provided as illustrated in FIG. 7, the output impedance of the voltage generation circuit 10D decreases to about several mΩ to 1 Ω

In this manner, the voltage generation circuit 10D according to the present embodiment includes the voltage follower circuit K1 and the LPF circuit K2 at a subsequent stage of the operational amplifier OP1, so that components in a high frequency band included in the output voltage of the voltage generation circuit 10D can be reduced, and the performance of generating a bias voltage can be improved.

### Fifth Embodiment

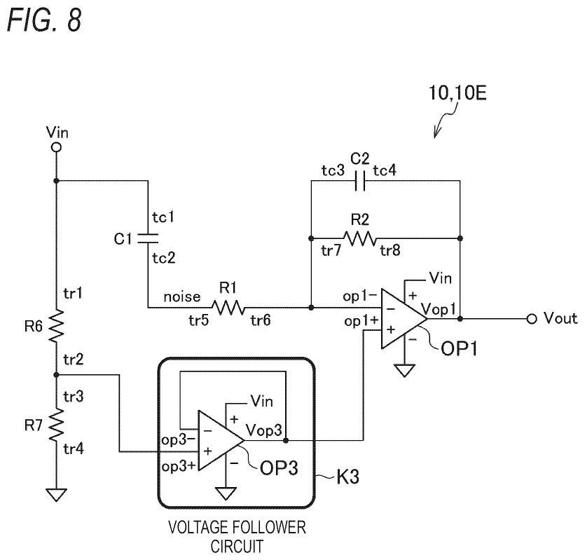

FIG. 8 is a circuit diagram illustrating an example of the voltage generation circuit 10E according to the fifth embodiment. The voltage generation circuit 10E is different from the voltage generation circuit 10B in that the voltage generation circuit 10D includes a voltage follower circuit K3. Regarding configurations of the voltage generation circuit 10E in FIG. 8 same as those of the voltage generation circuit 10A according to the first embodiment, the voltage generation circuit 10B according to the second embodiment, the voltage generation circuit 10C according to the third embodiment, or the voltage generation circuit 10D according to the fourth embodiment, the description thereof will be omitted or simplified.

The voltage generation circuit 10E includes the voltage follower circuit K3 in addition to the configuration of the voltage generation circuit 10B. The voltage follower circuit K3 includes an operational amplifier OP3.

The operational amplifier OP3 has an inverting input terminal op3−, a non-inverting input terminal op3+, and an output terminal Vop3. The inverting input terminal op3− is electrically connected to the output terminal Vop3. The non-inverting input terminal op3+ is electrically connected to the terminal tr2 and the terminal tr3. The output terminal Vop3 is electrically connected to the inverting input terminal op3− and the non-inverting input terminal op1+.

With such a configuration, it is possible to reduce an influence of an impedance between the operational amplifier OP1 and a connection point of the resistor R6 and the resistor R7. For example, a case in which a distance between the operational amplifier OP1 and the connection point of the resistor R6 and the resistor R7 is equal to or greater than a predetermined distance, or a case in which a predetermined noise source is present in the vicinity between the operational amplifier OP1 and the connection point of the resistor R6 and the resistor R7 is assumed. In this case, in a case where noise enters a path connecting the non-inverting input terminal op1+ and the connection point of the resistor R6 and the resistor R7, a voltage input to the non-inverting input terminal op1+ varies. For example, a DC-DC converter installed in the vicinity of the voltage generation circuit 10E is assumed as the predetermined noise source. Even when the noise source is not physically connected to any place in the voltage generation circuit 10E, in a case where the noise source and the voltage generation circuit 10E electrically interfere with each other, the voltage generation circuit 10E may be affected by the noise source by being installed in the vicinity of the voltage generation circuit 10E.

On the other hand, in the voltage generation circuit 10E, the voltage follower circuit K3 is disposed in a preceding stage of the non-inverting input terminal op1+, so that an operation of the operational amplifier OP1 can be stabilized, and thus the noise cancellation capability can be maintained.

It is possible to adopt a configuration in which at least two configurations of the voltage generation circuits 10 according to the above-described embodiments are combined. For example, the voltage generation circuit 10 may be configured by combining at least two of the third embodiment, the fourth embodiment, and the fifth embodiment. In the third embodiment, the fourth embodiment, and the fifth embodiment, the voltage generation circuit 10 may also not include the capacitor C2, similarly to the first embodiment. In each of the above-described embodiments, an amplifier circuit using a bias voltage generated by the voltage generation circuit 10 is not limited to the audio output circuit 100, and may be another circuit. For example, such an amplifier circuit is widely applicable to a circuit that performs amplification using a constant voltage, and may be a drive circuit of a motor.

### Sixth Embodiment

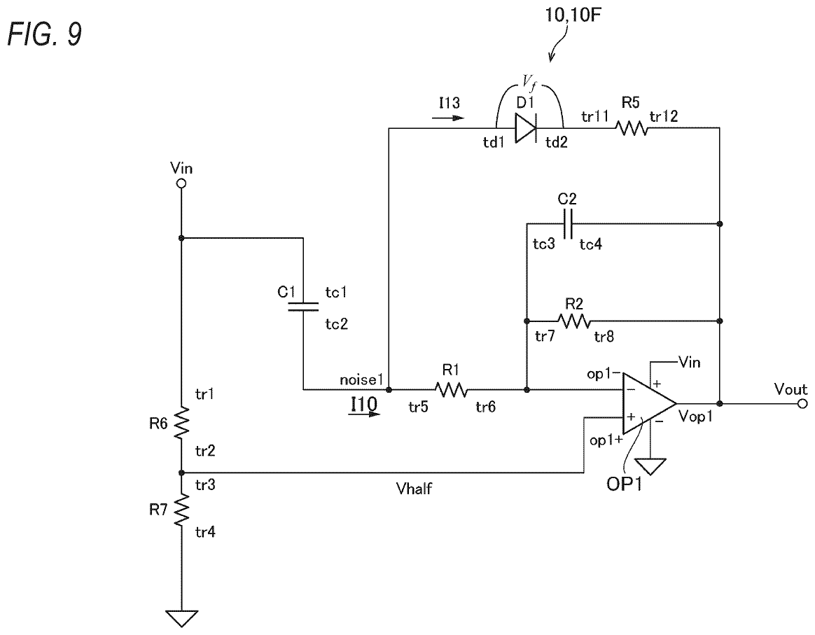

FIG. 9 is a circuit diagram illustrating an example of a voltage generation circuit 10F according to a sixth embodiment. The voltage generation circuit 10F is different from the voltage generation circuit 10B in that the voltage generation circuit 10F includes a diode D1 and a resistor R5. Regarding configurations of the voltage generation circuit 10F in FIG. 9 same as those of the voltage generation circuit 10A according to the first embodiment, the voltage generation circuit 10B according to the second embodiment, the voltage generation circuit 10C according to the third embodiment, the voltage generation circuit 10D according to the fourth embodiment, or the voltage generation circuit 10E according to the fifth embodiment, the description thereof will be omitted or simplified.

The voltage generation circuit 10F includes the diode D1 and the resistor R5 in addition to a configuration of the voltage generation circuit 10B.

The diode D1 has a diode terminal td1 and a diode terminal td2. Hereinafter, a terminal of a diode may be referred to as a diode terminal. The diode terminal td1 is electrically connected to the capacitive terminal tc2 and the terminal tr5. The diode D1 may be a rectifying diode or a Schottky diode.

The resistor R5 has a terminal tr11 and a terminal tr12. The terminal tr11 is electrically connected to the diode terminal td2. The terminal tr12 is electrically connected to the capacitive terminal tc4, the terminal tr8, the output terminal Vop1, and the voltage output terminal Vout. The resistor R5 limits a current flowing through the diode D1.

The voltage generation circuit 10F may not include the resistor R5. For example, when the current flowing through the diode D1 is small, that is, when the current flowing through the diode D1 is less than a predetermined current, installation of the resistor R5 may be omitted.

Next, a circuit operation of the voltage generation circuit 10F will be described.

In the voltage generation circuit 10F, in a case where a power supply is powered up, that is, when the input voltage Vin is applied, a voltage at a point noise1 between the capacitor C1 and the resistor R1 becomes a power supply voltage, that is, the input voltage Vin. The capacitor C1 does not allow a DC component to pass during a steady state, but allows an AC component to pass through at the time of a change from 0 V to 8 V, which is a power supply power-up time. A current amount passing through the capacitor C1 changes in accordance with the time from the power-up of the power supply. The voltage at the point noise1 is actually lower than the power supply voltage.

The operational amplifier OP1 controls the output voltage Vop1 so as to eliminate a potential difference between a voltage input to the inverting input terminal op1− and a voltage at a point Vhalf input to the non-inverting input terminal op1+. Specifically, since the voltage at the inverting input terminal op1− is higher than 4 V, the operational amplifier OP1 outputs, from the output terminal Vop1, a voltage obtained by reducing an amount of a difference between a potential (about 8 V) at the inverting input terminal op1− and a potential at the non-inverting input terminal op1+ (4 V) from 4 V. In this example, 4 V−4 V=0 V is output. Therefore, 0 V which is equal to the output voltage Vop1 is output as the output voltage Vout of the voltage generation circuit 10F. The output voltage Vop1 is the voltage at the output terminal Vop1.

In a state where the output voltage Vout is 0 V, a potential difference equal to or more than a forward voltage Vf occurs in a forward direction of the diode D1. Therefore, the diode D1 is turned ON, and a current flows. The forward voltage Vf is, for example, 0.7 V.

The voltage at the point noise1 is generated by a charge QC1 of the capacitor C1, and the charge is not replenished later. Therefore, the charge QC1 flows to the voltage output terminal Vout via the diode D1, and as a result, the voltage at the point noise1 decreases. In addition, as the voltage at the point noise1 decreases, the voltage input to the inverting input terminal op1− decreases, and the voltage at the output terminal Vop1 of the operational amplifier OP1 increases.

At a time point where the potential difference between the voltage at the point noise1 and the output voltage Vout becomes less than 0.7 V, the diode D1 is turned OFF, and a movement of the charge QC1 accumulated in the capacitor C1 is stopped. Accordingly, the voltage generation circuit 10F can rapidly increase the output voltage Vout until the output voltage Vout becomes (voltage at point Vhalf−0.7 V). In addition, the charge QC1 can be caused to flow more rapidly by reducing a resistance value of the resistor R5. Accordingly, the voltage generation circuit 10F can further rapidly increase the output voltage Vout.

A Schottky barrier diode having a low forward voltage Vf may be used as the diode D1. In this case, as compared with the case where a normal diode D1 is used, the voltage generation circuit 10F can rapidly increase, that is, rapidly rise, the output voltage Vout. The forward voltage Vf of the Schottky barrier diode is, for example, about 0.4 V or about 0.5 V.

Next, characteristics to be satisfied by the voltage generation circuit 10F will be described.

The resistance value, which is a constant of the resistor R5, is determined based on, for example, at least one of a time required for discharging the charge QC1 accumulated in the capacitor C1 and an upper limit of an operation current of the operational amplifier OP1. For example, as the resistance value of the resistor R5 is smaller, a rise time of the output voltage Vout is earlier, but the operation current of the operational amplifier OP1 increases. Therefore, the rise time of the output voltage Vout is set in consideration of a maximum operation current of the operational amplifier OP1. For example, when the resistance value of the resistor R5 is small, the current flows quickly, and thus the charge QC1 flows quickly and is discharged quickly.

A coefficient A is calculated by the following Equation (19) based on each constant of the voltage generation circuit 10F.

$$\begin{matrix}[ Math . 21 ] & \\ A = \frac{1}{{R}_{1}} + \frac{1}{{R}_{5}} + \frac{{R}_{2}}{{R}_{1} {R}_{5}} & ( 19 )\end{matrix}$$

Regarding each constant in Equation (19), as an example, a resistance value of the resistor R1 is 30 (kΩ), a resistance value of the resistor R2 is 30 (kΩ), and the resistance value of the resistor R5 is 400 (Ω). In this case, the coefficient A is 0.00503.

The operation current of the operational amplifier OP1 is calculate d by using the coefficient A. The maximum operation current of the operational amplifier OP1 is equal to a maximum value of a current I10 at the point noise 1 illustrated in FIG. 9. That is, it is represented by the following Equation (20).

$$\begin{matrix}[ Math . 22 ] & \\ I 10 = ( {V}_{c} - {V}_{p} ) A - \frac{1}{{R}_{5}} \cdot {V}_{f} & ( 20 )\end{matrix}$$

Regarding each constant of Equation (20), as an example, a voltage Vc at the point noise1 is 8 V, a voltage Vp at a connection point between the terminal tr2 and the terminal tr3 is 4 V, and the forward voltage Vf of the diode D1 is 0.7 V. In this case, the current I10 is 18.38 (mA). The voltage Vp is a voltage at the point Vhalf, and is a reference of a desired output voltage Vout.

A part of the current I10 flows through the operational amplifier OP1. Therefore, the current I needs to be equal to or less than an allowable current of the operational amplifier OP1. When the current I10 is allowed to be the maximum current of the operational amplifier OP1, a time constant is calculated. In a case where a time when the value of the output voltage Vout becomes 63.2% of a setting value of the output voltage Vout is a time constant τ(s), the time constant τ is calculated by the following Equation (21). The setting value is, for example, 4 V.

### Math. 23

$$Regarding τ = \frac{{C}_{1}}{A + \frac{{V}_{f}}{{R}_{5} ( {V}_{c} - {V}_{p} )}} ( s ) \qquad ( 21 )$$

example, a capacitance value of the capacitor C1 is 10 μF. In this case, the time constant τ is 2.18 (ms).

In the voltage generation circuit 10B according to the second embodiment in which the diode D1 and the resistor R5 according to the present embodiment are not inserted, a time constant τ′ is calculated by the following Equation (22).

$${τ}^{′} = C 1 \cdot R 1 \qquad ( 22 )$$

Regarding each constant in Equation (22), as an example, in a case where the capacitance value C1 and the resistance value R1 in the present embodiment are set to the same value, the time constant τ′ is 300 (ms).

Therefore, the voltage generation circuit 10F rises by about 137 times quicker than the voltage generation circuit 10B.

The voltage Vc changes from 0 V to an upper limit value of the voltage Vc. A maximum value of the upper limit value of the voltage Vc is the input voltage Vin. As the rise time of the output voltage Vout is later, the upper limit value of the voltage Vc decreases. In practice, the forward voltage Vf of the diode D1 may change over time due to the current flowing through the diode D1. In this example, each equation is calculated assuming that the forward voltage Vf is a constant value.

Next, a forward allowable current of the diode D1 will be described.

The forward allowable current of the diode D1 is an upper limit value allowed as a current flowing in the forward direction of the diode D1. The diode D1 is selected, for example, taking into consideration at least one of the following: a current value flowing through the resistor R5 is equal to or less than the forward allowable current of the diode D1; the forward voltage Vf is smaller than the potential difference between the input voltage Vin and the output voltage Vout; and a reverse current is small.

A maximum current I13 flowing through the diode D1 and the resistor R5 is calculated by the following Equation (23). A calculation result is compared with the forward allowable current of the diode D1.

$$\begin{matrix}[ Math . 24 ] & \\ {I}_{13} = ( \frac{1}{{R}_{5}} + \frac{{R}_{2}}{{R}_{1} {R}_{5}} ) ( {V}_{c} - {V}_{p} ) - \frac{1}{{R}_{5}} {V}_{f} & ( 23 )\end{matrix}$$

That is, the current I13 is calculated based on the voltage Vc passing through the capacitor C1 and the voltage Vp scheduled to be output as the output voltage Vout. Regarding each constant of Equation (23), as an example, the voltage Vc at the point noise1 is 8 V, the output voltage Vout is 4 V, the forward voltage Vf of the diode D1 is 0.7 V, the resistance value of the resistor R1 is 30 (kΩ), the resistance value of the resistor R2 is 30 (kΩ), the resistance value of the resistor R5 is 400 (22), and the capacitance value of the capacitor C1 is 10 (μF). In this case, the maximum current I13 is 18.25 (mA). Therefore, a diode whose forward allowable current is larger than 18.25 (mA) is selected as the diode D1.

A diode whose forward voltage Vf of the diode D1 is smaller than the potential difference of (Vc−Vout) is selected as the diode D1. As the forward voltage Vf of the diode D1 decreases, the rise time of the output voltage Vout can be shortened. For example, the forward voltage Vf of a PN junction diode formed of a silicon semiconductor is about 0.7 V. On the other hand, since the forward voltage Vf of the Schottky barrier diode is about 0.5 V, the forward voltage Vf can be made smaller than that of the PN junction diode formed of a silicon semiconductor, and the rise time of the output voltage Vout can be shortened. As the diode D1, a PN junction diode using a germanium semiconductor instead of a silicon semiconductor or another diode may be used. The forward voltage Vf may be taken into consideration for the selection of the diode D1.

There is a phenomenon that a current flows through the diode D1 in a reverse direction. This is called a reverse current, and when a value of the reverse current is large, the noise removal performance by the diode D1 and the resistor R5 may deteriorate. For example, in the PN junction diode formed of a silicon semiconductor, the reverse current is about 140 nA, and the noise removal performance is not substantially deteriorated. The noise removal performance is, for example, a power supply rejection ratio (PSRR) characteristic. On the other hand, in the Schottky barrier diode or the like, the reverse current is about 50 uA, and the noise removal performance may be deteriorated. Such a reverse current may be taken into consideration for the selection of the diode D1.

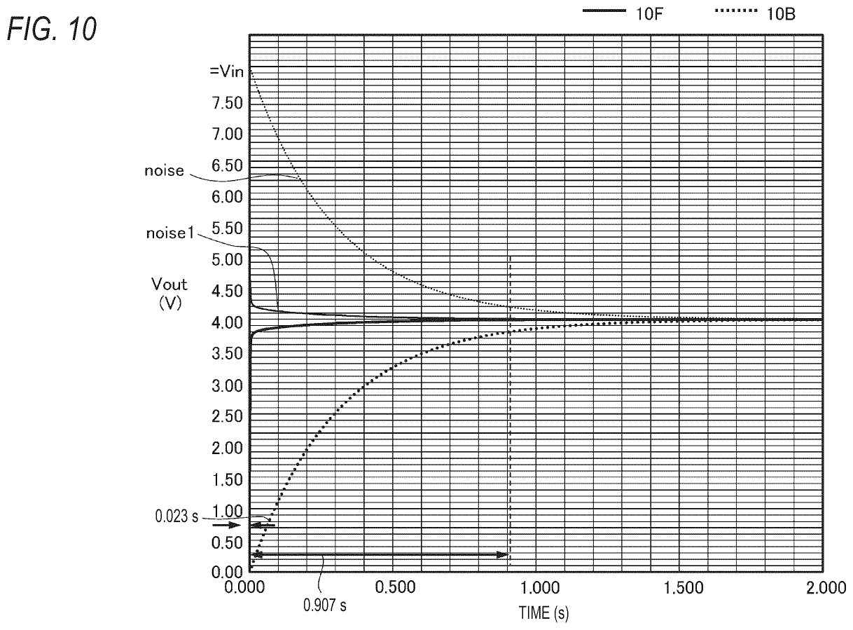

FIG. 10 is a diagram illustrating an example of the output voltage Vout of the voltage generation circuit 10B according to the second embodiment and the output voltage Vout of the voltage generation circuit 10F according to the present embodiment. FIG. 10 also illustrates an example of a voltage at a point noise in the voltage generation circuit 10B and the voltage at the point noise1 in the voltage generation circuit 10F. In FIG. 10, the voltage at the point noise is simply referred to as “noise”, and the voltage at the point noise1 is simply referred to as “noise1”.

In the voltage generation circuit, in a case where the capacitance value of the capacitor C1 or the value of the resistor R1 is increased, the noise removal capability is improved, but the time required for the rise of the output voltage Vout tends to be long. The resistance value of the resistor R1 is equal to the resistance value of the resistor R2.

For example, in a case where the constant of the capacitor C1 is increased, the noise removal capability of the audio band increases, but the time required for the rise of the output voltage Vout is prolonged. Therefore, the time required for activation of the audio output circuit 100 is also prolonged. On the other hand, the voltage generation circuit 10F according to the present embodiment can shorten the time taken for the rise of the output voltage Vout.

Referring to FIG. 10, it can be understood that the voltage at the point noise1 of the voltage generation circuit 10F rapidly rises from 0 V to the vicinity of the input voltage Vin, rapidly drops from the vicinity of the input voltage Vin to the vicinity of (4+0.7 V), and then smoothly converges to the vicinity of 4 V. A period during which the voltage smoothly converges is the same behavior as when the diode D1 and the resistor R5 are absent. In addition, it can be understood that the output voltage Vout of the voltage generation circuit 10F rapidly rises from 0 V and converges to the vicinity of 4 V corresponding to the voltage at the point noise1. The same applies to the voltage at the point noise of the voltage generation circuit 10B and the output voltage Vout. However, the rise time of the output voltage Vout of the voltage generation circuit 10F, that is, the time constant τ is 0.022 seconds, and the rise time of the output voltage Vout of the voltage generation circuit 10B, that is, the time constant τ is 0.907 seconds. In the voltage generation circuit 10F here, the resistance value of the resistor R5 is 200 Ω as an example. In this case, the voltage generation circuit 10F can also significantly shorten the rise time of the voltage generation circuit 10B.

### First Modification of Sixth Embodiment

The voltage generation circuit 10F may include a transistor instead of the diode D1. The transistor is a bipolar transistor and has a base terminal, a collector terminal, and an emitter terminal. The base terminal and the collector terminal are electrically connected to the capacitive terminal tc2 and the terminal tr5. The emitter terminal of the transistor is electrically connected to the terminal tr11. Even when the voltage generation circuit 10F includes a transistor instead of the diode D1, the same effect as in the case where the voltage generation circuit 10F includes the diode D1 can be exerted.

### Second Modification of Sixth Embodiment

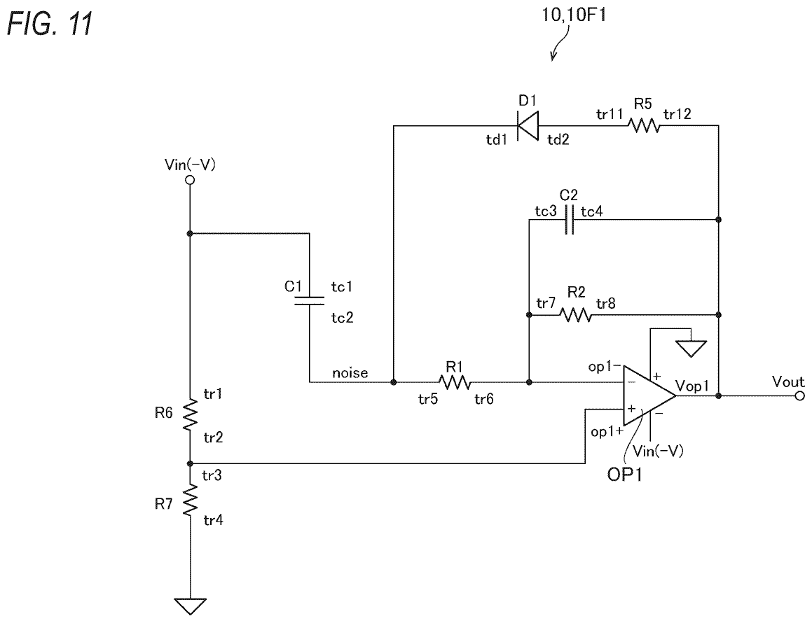

FIG. 11 is a circuit diagram illustrating an example of a voltage generation circuit 10F1 which is a modification of the voltage generation circuit 10F. The voltage generation circuit 10F1 is different from the voltage generation circuit 10F in the following points. Specifically, the operational amplifier OP1 is not an operational amplifier with a positive single power supply but an operational amplifier with a negative single power supply. Orientation of the diode D1 of the voltage generation circuit 10F1 is opposite to orientation of the diode D1 of the voltage generation circuit 10F. That is, a forward direction of the diode D1 is not a direction from the diode D1 toward the resistor R5 but a direction from the resistor R5 toward the diode D1. Even with such a configuration of the voltage generation circuit 10F1, the same effects as those of the voltage generation circuit 10F can be exerted.

The first modification and the second modification of the present embodiment may be combined.

In the present embodiment, the voltage generation circuit 10F has a configuration in which the diode D1 and the resistor R5 are added to the voltage generation circuit 10B, but the present invention is not limited thereto. For example, the voltage generation circuit 10F may have a configuration in which the diode D1 and the resistor R5 are added to the voltage generation circuit 10A according to the first embodiment, the voltage generation circuit 10C according to the third embodiment, the voltage generation circuit 10D according to the fourth embodiment, or the voltage generation circuit 10E according to the fifth embodiment. With such a configuration, the same effects as those of the voltage generation circuit 10F can also be exerted.

### Seventh Embodiment

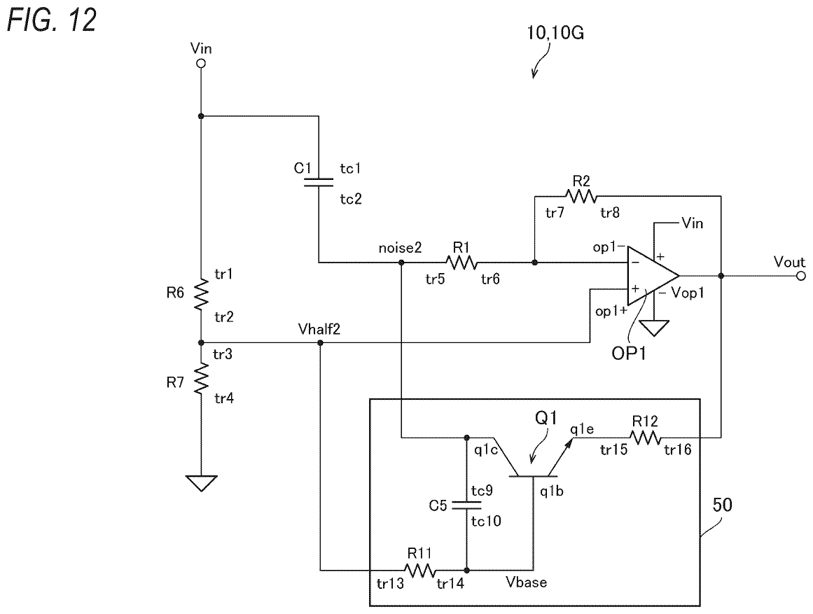

FIG. 12 is a circuit diagram illustrating an example of a voltage generation circuit 10G according to a seventh embodiment. The voltage generation circuit 10G is different from the voltage generation circuit 10A in that the voltage generation circuit 10G includes an additional circuit 50. Regarding configurations of the voltage generation circuit 10G in FIG. 12 same as those of the voltage generation circuit 10A according to the first embodiment, the voltage generation circuit 10B according to the second embodiment, the voltage generation circuit 10C according to the third embodiment, the voltage generation circuit 10D according to the fourth embodiment, and the voltage generation circuit 10E according to the fifth embodiment, the description thereof will be omitted or simplified.

The voltage generation circuit 10G includes the additional circuit 50 in addition to the configuration of the voltage generation circuit 10A. The additional circuit 50 includes a transistor Q1, a capacitor C5, a resistor R11, and a resistor R12. The capacitor C5 has a capacitive terminal tc9 and a capacitive terminal tc10. The resistor R11 has a terminal tr13 and a terminal tr14. The resistor R12 has a terminal tr15 and a terminal tr16.

The transistor Q1 is a bipolar transistor and has a base terminal q1b, a collector terminal q1c, and an emitter terminal q1e. The base terminal q1b is electrically connected to the terminal tr14 and the capacitive terminal tc10. The collector terminal q1c is electrically connected to the capacitive terminal tc2, the terminal tr5, and the capacitive terminal tc9. The emitter terminal q1e is electrically connected to the terminal tr15.

In the resistor R11, the terminal tr13 is electrically connected to the terminal tr2, the terminal tr3, and the non-inverting input terminal op1+. In the resistor R12, the terminal tr16 is electrically connected to the terminal tr8, the output terminal Vop1, and the voltage output terminal Vout.

The capacitor C5 is used to prevent oscillation of the operational amplifier OP1. A capacitance value of the capacitor C5 may be any value of, for example, 1 pF to 100 pF, but is preferably the smallest capacitance value to an extent that the operational amplifier OP1 does not oscillate. The voltage generation circuit 10G may not include the capacitor C5. The resistor R11 limits a magnitude of a base current of the transistor Q1. The voltage generation circuit 10G may not include the resistor R11.

Combination of resistance values of the resistor R6, the resistor R7, the resistor R11, and the resistor R12 is selected so that the output voltage Vout in a steady state of the voltage generation circuit 10G is a predetermined value. The output voltage Vout is, for example, 4 V. For example, the resistance value of the resistor R6 is 10 kΩ, the resistance value of the resistor R7 is 10 kΩ, the resistance value of the resistor R11 is 0 Ω, and the resistance value of the resistor R6 is 20 Ω. The resistance value of each resistor may be determined according to an amplification factor of the transistor Q1.

Next, a circuit operation of the voltage generation circuit 10G will be described.

In the voltage generation circuit 10G, in a case where the power supply is powered up, that is, when the input voltage Vin is applied, a voltage at a point noise2 between the capacitor C1 and the resistor R1 becomes a power supply voltage, that is, the input voltage Vin. The capacitor C1 does not allow a DC component to pass during a steady state, but allows an AC component to pass through at the time of a change from 0 V to 8 V, which is a power supply power-up time. A current amount passing through the capacitor C1 changes due to the change time, and the voltage at the point noise2 is actually smaller than the power supply voltage.

The operational amplifier OP1 controls the voltage of the output voltage Vop1 so as to eliminate a potential difference between a voltage input to the inverting input terminal op1− and a voltage at a point Vhalf2 input to the non-inverting input terminal op1+. Therefore, the output voltage Vout of the voltage generation circuit 10G equal to the voltage of the output voltage Vop1 outputs 0 V. Specifically, due to the current flowing from the point Vhalf2 to the transistor Q1, the voltage at the point Vhalf2 is lower than a voltage obtained by dividing the input voltage Vin by the resistor R3 and the resistor R4. Therefore, the voltage at the point Vhalf2 is about 2 V with respect to 4 V, which is a setting value of the output voltage Vout, and the output voltage Vout outputs a voltage lower than 0 V. However, since a negative side of a power supply terminal of the operational amplifier OP1 is electrically connected to 0 V, the actual output voltage Vout is 0 V.

In a state where the output voltage Vout is 0 V, the current is supplied from the point Vhalf2 to the transistor Q1 connected to the point noise2. Therefore, a current obtained by multiplying the base current by a current amplification factor hfe flows from the point noise2 to the voltage output terminal Vout via the resistor R12.

The voltage at the point noise2 is generated by the charge QC1 of the capacitor C1, and the charge is not replenished later. Therefore, the charge QC1 flows to the voltage output terminal Vout via the transistor Q1, and as a result, the voltage at the point noise2 decreases. In addition, as the voltage at the point noise2 decreases, the voltage input to the inverting input terminal op1− of the operational amplifier OP1 decreases, and the voltage at the output terminal Vop1 increases.

When the voltage at the point noise2 becomes 4 V which is the setting value of the output voltage Vout, the voltages at the inverting input terminal op1− and the non-inverting input terminal op1+ are reversed, and the voltage at the voltage output terminal Vout is output as a voltage in a positive direction, that is, having a positive value. That is, as the voltage at the point noise2 decreases, the voltage at the point noise2 and the output voltage Vout are divided by the resistor R1 and the resistor R2 and become a voltage in the vicinity of 2 V. When the voltage at the point noise2 becomes lower than 4 V, the voltage at the inverting input terminal op1− becomes smaller than 2 V which is the voltage at the point Vhalf2. Accordingly, the voltage at the voltage output terminal Vout becomes a voltage having a positive value.

In a case where the voltage at the voltage output terminal Vout rises, the base current decreases as the emitter current of the transistor Q1 decreases, the voltage at the point Vhalf2 increases, and the voltage at the voltage output terminal Vout further increases.

When the voltage at the point noise2 becomes equal to the output voltage Vout, the emitter current of the transistor Q1 does not flow. Accordingly, the charge QC1 of the capacitor C1 does not flow to the voltage output terminal Vout via the transistor Q1. Therefore, the voltage at the point noise2 stops decreasing, and at the same time, the voltage at the point Vhalf2 becomes 4 V, which is the voltage obtained by dividing the input voltage Vin by the resistor R3 and resistor R4, and the output voltage at the voltage output terminal Vout becomes 4 V.

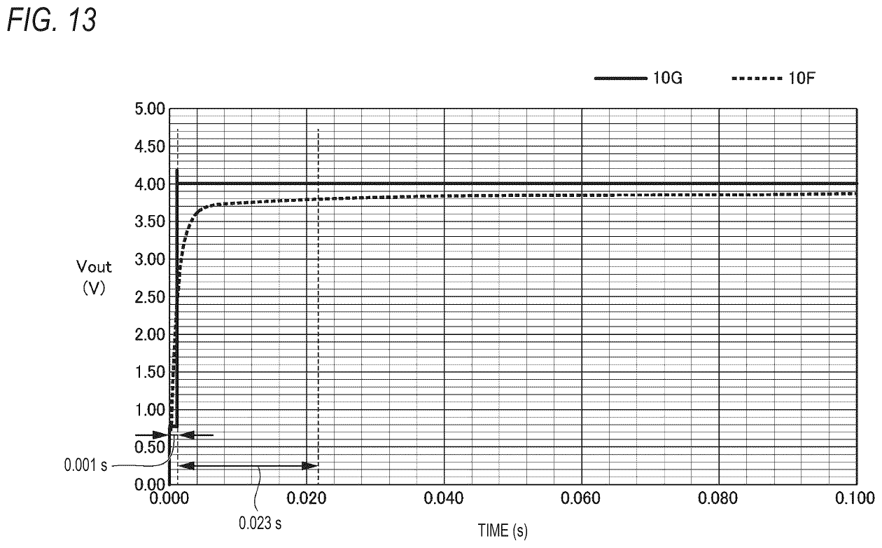

FIG. 13 is a diagram illustrating an example of the output voltage Vout of the voltage generation circuit 10F according to the sixth embodiment and the output voltage Vout of the voltage generation circuit 10G according to the present embodiment.

In a case where the capacitance value of the capacitor C1, the resistance value of the resistor R1, or the resistance value of the resistor R2 is increased in the voltage generation circuit, the noise removal capability is improved, but the rise time of the output voltage Vout tends to extend.

Both the voltage generation circuit 10F and the voltage generation circuit 10G can quickly shorten the rise time of the output voltage Vout. In addition, the voltage generation circuit 10G can improve the noise removal performance in a low band of less than 1 kHz. As illustrated in FIG. 13, the rise time of the output voltage Vout by the voltage generation circuit 10G is 0.001 (ms), and the rise time of the output voltage Vout by the voltage generation circuit 10F is 0.023 (ms). That is, the voltage generation circuit 10G can further rapidly shorten the rise time of the output voltage Vout compared to the voltage generation circuit 10F. On the other hand, according to the voltage generation circuit 10F, when the diode D1 is used without using a transistor, the voltage generation circuit 10F does not generate a manufacturing variation in the current amplification factor hfe of the transistor. Therefore, the voltage generation circuit 10F can shorten the rise time of the output voltage Vout independently of the individual diode D1. In addition, the voltage generation circuit 10F can improve the noise removal performance in a low band of less than 1 kHz and a med-high band of 1 kHz or more.

In the present embodiment, the voltage generation circuit 10G has a configuration in which the additional circuit 50 is added to the voltage generation circuit 10A, but the present invention is not limited thereto. For example, the voltage generation circuit 10F may have a configuration in which the additional circuit 50 is added to the voltage generation circuit 10B according to the second embodiment, the voltage generation circuit 10C according to the third embodiment, the voltage generation circuit 10D according to the fourth embodiment, or the voltage generation circuit 10E according to the fifth embodiment. With such a configuration, the same effects as those of the voltage generation circuit 10F can also be exerted. However, the voltage generation circuit 10G is not applied to a case where the operational amplifier OP1 is with a negative single power supply.

### Note

The following techniques are disclosed according to the above description of embodiments.

### Technique 1

A voltage generation circuit including:

a voltage input terminal to which an input voltage is input;

a voltage output terminal from which an output voltage is output;

a first resistor having a first terminal and a second terminal, the first terminal being electrically connected to the voltage input terminal;

a second resistor having a third terminal and a fourth terminal, the third terminal being electrically connected to the second terminal, and the fourth terminal being electrically connected to a ground potential;

a first capacitor having a first capacitive terminal and a second capacitive terminal, the first capacitive terminal being electrically connected to the voltage input terminal;

a third resistor having a fifth terminal and a sixth terminal, the fifth terminal being electrically connected to the second capacitive terminal;

a fourth resistor having a seventh terminal and an eighth terminal, the seventh terminal being electrically connected to the sixth terminal; and

a first operational amplifier having a first inverting input terminal, a first non-inverting input terminal, and a first output terminal, the first inverting input terminal being electrically connected to the sixth terminal, the first non-inverting input terminal being electrically connected to the second terminal, and the first output terminal being electrically connected to the voltage output terminal and the eighth terminal.

The voltage generation circuit is, for example, the voltage generation circuit 10. The voltage input terminal is, for example, the voltage input terminal Vin. The voltage output terminal is, for example, the voltage output terminal Vout. The first terminal is, for example, the terminal tr1. The second terminal is, for example, the terminal tr2. The first resistor is, for example, the resistor R6. The third terminal is, for example, the terminal tr3. The fourth terminal is, for example, the terminal tr4. The second resistor is, for example, the resistor R7. The first capacitive terminal is, for example, the capacitive terminal tc1. The second capacitive terminal is, for example, the capacitive terminal tc2. The first capacitor is, for example, the capacitor C1. The fifth terminal is, for example, the terminal tr5. The sixth terminal is, for example, the terminal tr6. The third resistor is, for example, the resistor R1. The seventh terminal is, for example, the terminal tr7. The eighth terminal is, for example, the terminal tr8. The fourth resistor is, for example, the resistor R2. The first output terminal is, for example, the output terminal Vop1. The first operational amplifier is, for example, the operational amplifier OP1.

With this configuration, the voltage generation circuit extracts, by the first capacitor, a power supply variation component of the input voltage input from the voltage input terminal, applies the power supply variation component to the inverting input terminal of the first operational amplifier, and feeds back a signal output from the first operational amplifier OP. Accordingly, the voltage generation circuit can cancel the variation component at a point divided by the first resistor and the second resistor. The voltage generation circuit does not need to include a large capacitor in order to remove noise. Therefore, the voltage generation circuit can suppress an increase in size of a device including the voltage generation circuit, and can suppress the variation component of the input voltage from being voltage-applied to the output voltage. Accordingly, it is possible to improve a voltage generation circuit that generates a midpoint bias voltage with noise cancelled.

### Technique 2

The voltage generation circuit according to Technique 1, in which

a ratio of a first resistance value which is a resistance value of the first resistor to a second resistance value which is a resistance value of the second resistor is equal to a ratio of a third resistance value which is a resistance value of the third resistor to a fourth resistance value which is a resistance value of the fourth resistor.

With this configuration, the voltage generation circuit can generate the output voltage output from the voltage generation circuit while maintaining a ratio of the voltage divided by the first resistor and the second resistor and maintaining the noise cancellation capability. The voltage generation circuit can adjust the bias voltage based on the ratio of the voltage.

### Technique 3

The voltage generation circuit according to Technique 2, in which

the first resistance value is equal to the second resistance value, and

the third resistance value is equal to the fourth resistance value.

With this configuration, the voltage generation circuit can obtain a voltage half of the input voltage to the voltage generation circuit by division with the first resistor and the second resistor, and can generate the output voltage output from the voltage generation circuit while maintaining the noise cancellation capability.

### Technique 4

The voltage generation circuit according to Technique 2, in which

the first resistance value is different from the second resistance value, and

the third resistance value is different from the fourth resistance value.

With this configuration, the voltage generation circuit can obtain a voltage shifted by a predetermined value from the half of the input voltage to the voltage generation circuit by division with the first resistor and the second resistor, and can generate the output voltage output from the voltage generation circuit while maintaining the noise cancellation capability.

### Technique 5

The voltage generation circuit according to any of Technique 1 to Technique 4, in which

the third resistance value is larger than the first resistance value, and

the fourth resistance value is larger than the second resistance value.

### Technique 6

The voltage generation circuit according to any of Technique 1 to Technique 5, further including:

a second capacitor having a third capacitive terminal and a fourth capacitive terminal, the third capacitive terminal being electrically connected to the seventh terminal, and the fourth capacitive terminal being electrically connected to the first output terminal.

The third capacitive terminal is, for example, the capacitive terminal tc3. The fourth capacitive terminal is, for example, the capacitive terminal tc4. The second capacitor is, for example, the capacitor C2.

With this configuration, the voltage generation circuit can suppress oscillation of the first operational amplifier in a high frequency band, and can stably maintain the noise cancellation capability.

### Technique 7

The voltage generation circuit according to Technique 6, in which a first capacitance value which is a capacitance value of the first capacitor is larger than a second capacitance value which is a capacitance value of the second capacitor.

### Technique 8

The voltage generation circuit according to any of Technique 1 to Technique 7, further including:

a third capacitor having a fifth capacitive terminal and a sixth capacitive terminal, the fifth capacitive terminal being electrically connected to the first output terminal of the first operational amplifier and the voltage output terminal, and the sixth capacitive terminal being electrically connected to the ground potential.

The fifth capacitive terminal is, for example, the capacitive terminal tc5. The sixth capacitive terminal is, for example, the capacitive terminal tc6. The third capacitor is, for example, the capacitor C3.

With this configuration, the third capacitor can allow an AC component in a high frequency band of the signal output from the first output terminal of the first operational amplifier to pass, and does not allow a DC component to pass. Accordingly, the voltage generation circuit can reduce the AC component in the high frequency band, and can reduce a noise component superimposed on the high frequency band of the output voltage.

### Technique 9

The voltage generation circuit according to any of Technique 1 to Technique 7, further including:

a fifth resistor having a ninth terminal and a tenth terminal, the ninth terminal being connected to the first output terminal of the first operational amplifier;

a fourth capacitor having a seventh capacitive terminal and an eighth capacitive terminal, the seventh capacitive terminal being connected to the tenth terminal and the eighth capacitive terminal being electrically connected to the ground potential; and a second operational amplifier having a second inverting input terminal, a second non-inverting input terminal, and a second output terminal, the second inverting input terminal being electrically connected to the second output terminal, the second non-inverting input terminal being electrically connected to the tenth terminal, and the second output terminal being electrically connected to the voltage output terminal.

The ninth terminal is, for example, the terminal tr9. The tenth terminal is, for example, the terminal tr10. The fifth resistor is, for example, the resistor R4. The seventh capacitive terminal is, for example, the capacitive terminal tc7. The eighth capacitive terminal is, for example, the capacitive terminal tc8. The fourth capacitor is, for example, the capacitor C4.

The second output terminal is, for example, the output terminal Vop2. The second operational amplifier is, for example, the operational amplifier OP2.

With this configuration, in the voltage generation circuit, the second operational amplifier operates as a voltage follower circuit, and the fifth resistor and the fourth capacitor operate as an RC LPF circuit. Accordingly, the voltage generation circuit can further reduce components in the high frequency band included in the output voltage. The voltage generation circuit can reduce an output impedance and may output a constant output voltage without depending on a load of a device to which the voltage generation circuit is connected.

### Technique 10

The voltage generation circuit according to any of Technique 1 to Technique 7, further including:

a third operational amplifier having a third inverting input terminal, a third non-inverting input terminal, and a third output terminal, the third inverting input terminal being electrically connected to the third output terminal, the third non-inverting input terminal being electrically connected to the second terminal, and the third output terminal being electrically connected to the first non-inverting input terminal of the first operational amplifier.

The third output terminal is, for example, the output terminal Vop3. The third operational amplifier is, for example, the operational amplifier OP3.

With this configuration, in the voltage generation circuit, the third operational amplifier disposed in a preceding stage of the first operational amplifier operates as the voltage follower circuit. Accordingly, the voltage generation circuit can maintain the voltage input to the non-inverting input terminal of the first operational amplifier to be constant. Accordingly, the voltage generation circuit can stabilize the operation of the operational amplifier OP1 and can generate a bias voltage while maintaining the noise cancellation capability.

### Technique 11

The voltage generation circuit according to any of Technique 1 to Technique 10, further including:

a diode having a first diode terminal and a second diode terminal, the first diode terminal being electrically connected to the second capacitive terminal, and the second diode terminal being electrically connected to the first output terminal.

The first diode terminal is, for example, the diode terminal td1. The second diode terminal is, for example, the diode terminal td2.

With this configuration, the voltage generation circuit can shorten the rise time of the output voltage while maintaining the noise removal capability in the entire audio band. The entire audio band here is, for example, 20 Hz to 20 kHz.

### Technique 12

The voltage generation circuit according to Technique 11, further including:

a sixth resistor having an eleventh terminal and a twelfth terminal, the eleventh terminal being electrically connected to the second diode terminal, and the twelfth terminal being electrically connected to the first output terminal.

The eleventh terminal is, for example, the terminal tr11. The twelfth terminal is, for example, the terminal tr12. The sixth resistor is, for example, the resistor R5.

With this configuration, the voltage generation circuit can suppress an excessive current from flowing through the diode.

### Technique 13

The voltage generation circuit according to any of Technique 1 to Technique 10, further including:

a transistor having a base terminal, a collector terminal, and an emitter terminal, the base terminal being electrically connected to the second terminal, and the collector terminal being electrically connected to the second capacitive terminal; and

a seventh resistor having a thirteenth terminal and a fourteenth terminal, the thirteenth terminal being electrically connected to the emitter terminal, and the fourteenth terminal being electrically connected to the first output terminal.

The base terminal is, for example, the base terminal q1b. The collector terminal is, for example, the collector terminal q1c. The emitter terminal is, for example, the emitter terminal q1e. The transistor is, for example, the transistor Q1. The thirteenth terminal is, for example, the terminal tr15. The fourteenth terminal is, for example, the terminal tr16. The seventh resistor is, for example, the resistor R12.

With this configuration, the voltage generation circuit can significantly shorten the rise time of the output voltage while maintaining the noise removal performance in a low band of the audio band. The low band of the audio band is, for example, less than 1 kHz.

### Technique 14

The voltage generation circuit according to Technique 13, further including:

a fifth capacitor having a ninth capacitive terminal and a tenth capacitive terminal, the ninth capacitive terminal being electrically connected to the collector terminal and the second capacitive terminal, and the tenth capacitive terminal being electrically connected to the base terminal and the second terminal.

The ninth capacitive terminal is, for example, the capacitive terminal tc9. The tenth capacitive terminal is, for example, the capacitive terminal tc10. The fifth capacitor is, for example, the capacitor C5.

With this configuration, when the voltage generation circuit includes a transistor, it is possible to suppress oscillation of the first operational amplifier in the high frequency band and to stably maintain the noise removal performance.

### Technique 15

The voltage generation circuit according to Technique 13, further including:

an eighth resistor having a fifteenth terminal and a sixteenth terminal, the fifteenth terminal being electrically connected to the second terminal, and the sixteenth terminal being electrically connected to the base terminal and the tenth capacitive terminal.

The fifteenth terminal is, for example, the terminal tr13. The sixteenth terminal is, for example, the terminal tr14. The eighth resistor is, for example, the resistor R11.

With this configuration, the voltage generation circuit can suppress an excessive base current from flowing through the transistor.

### Technique 16

An audio output circuit including:

the voltage generation circuit according to any of Technique 1 to Technique 15; and

a fourth operational amplifier, in which

the fourth operational amplifier has

a first input terminal, a second input terminal, and a fourth output terminal,

an output voltage output by the voltage generation circuit is input to the first input terminal,

an audio input signal is input to the second input terminal, and

an audio output signal based on the audio input signal is output from the fourth output terminal.

The fourth operational amplifier is, for example, the operational amplifier OP10. The first input terminal is, for example, an inverting input terminal of the fourth operational amplifier. The second input terminal is, for example, a non-inverting input terminal of the fourth operational amplifier. The fourth output terminal is the output terminal Vop10. The audio output circuit is, for example, the audio output circuit 100.

With this configuration, the audio output circuit can input the output voltage generated by the voltage generation circuit to the fourth operational amplifier and use the output voltage as the bias voltage. Therefore, even when the audio input signal is amplified, the audio output circuit can keep the voltage of the signal within a range in which the fourth operational amplifier may process, and can suitably perform amplification processing of the audio signal.

Although various embodiments have been described above with reference to the drawings, it is needless to say that the present invention is not limited to these embodiments. It is apparent that those skilled in the art can conceive of various modifications and alterations within the scope described in the claims, and it is understood that such modifications and alterations naturally fall within the technical scope of the present invention. In addition, the components in the above embodiment may be freely combined in a range without deviating from the spirit of the invention.

The present disclosure is based on Japanese Patent Application No. 2022-158437 filed on Sep. 30, 2022, and the contents thereof are incorporated herein by reference.

### INDUSTRIAL APPLICABILITY

The present disclosure is useful for a voltage generation circuit capable of generating a voltage by reducing a variation component superimposed on an input voltage, an audio output circuit, and the like.

### CROSS-REFERENCE TO RELATED APPLICATIONS

This is a continuation of International Application No. PCT/JP2023/016985 filed on Apr. 28, 2023, and claims priority from Japanese Patent Application No. 2022-158437 filed on Sep. 30, 2022, the entire contents of which are incorporated herein by reference.

What is claimed is:

1. A voltage generation circuit comprising:
a voltage input terminal to which an input voltage is input;
a voltage output terminal from which an output voltage is output;
a first resistor having a first terminal and a second terminal, the first terminal being electrically connected to the voltage input terminal;
a second resistor having a third terminal and a fourth terminal, the third terminal being electrically connected to the second terminal, and the fourth terminal being electrically connected to a ground potential;
a first capacitor having a first capacitive terminal and a second capacitive terminal, the first capacitive terminal being electrically connected to the voltage input terminal;
a third resistor having a fifth terminal and a sixth terminal, the fifth terminal being electrically connected to the second capacitive terminal;
a fourth resistor having a seventh terminal and an eighth terminal, the seventh terminal being electrically connected to the sixth terminal; and
a first operational amplifier having a first inverting input terminal, a first non-inverting input terminal, and a first output terminal, the first inverting input terminal being electrically connected to the sixth terminal, the first non-inverting input terminal being electrically connected to the second terminal, and the first output terminal being electrically connected to the voltage output terminal and the eighth terminal.

2. The voltage generation circuit according to claim 1, wherein
a ratio of a first resistance value which is a resistance value of the first resistor to a second resistance value which is a resistance value of the second resistor is equal to a ratio of a third resistance value which is a resistance value of the third resistor to a fourth resistance value which is a resistance value of the fourth resistor.

3. The voltage generation circuit according to claim 2, wherein
the first resistance value is equal to the second resistance value, and
the third resistance value is equal to the fourth resistance value.

4. The voltage generation circuit according to claim 2, wherein
the first resistance value is different from the second resistance value, and
the third resistance value is different from the fourth resistance value.

5. The voltage generation circuit according to claim 2, wherein
the third resistance value is larger than the first resistance value, and
the fourth resistance value is larger than the second resistance value.

6. The voltage generation circuit according to claim 1, further comprising:
a second capacitor having a third capacitive terminal and a fourth capacitive terminal, the third capacitive terminal being electrically connected to the seventh terminal, and the fourth capacitive terminal being electrically connected to the first output terminal.

7. The voltage generation circuit according to claim 6, wherein
a first capacitance value which is a capacitance value of the first capacitor is larger than a second capacitance value which is a capacitance value of the second capacitor.

8. The voltage generation circuit according to claim 1, further comprising:
a third capacitor having a fifth capacitive terminal and a sixth capacitive terminal, the fifth capacitive terminal being connected to the first output terminal of the first operational amplifier and the voltage output terminal, and the sixth capacitive terminal being electrically connected to the ground potential.

9. The voltage generation circuit according to claim 1, further comprising:
a fifth resistor having a ninth terminal and a tenth terminal, the ninth terminal being connected to the first output terminal of the first operational amplifier;
a fourth capacitor having a seventh capacitive terminal and an eighth capacitive terminal, the seventh capacitive terminal being connected to the tenth terminal and the eighth capacitive terminal being electrically connected to the ground potential; and
a second operational amplifier having a second inverting input terminal, a second non-inverting input terminal, and a second output terminal, the second inverting input terminal being electrically connected to the second output terminal, the second non-inverting input terminal being electrically connected to the tenth terminal, and the second output terminal being electrically connected to the voltage output terminal.

10. The voltage generation circuit according to claim 1, further comprising:
a third operational amplifier having a third inverting input terminal, a third non-inverting input terminal, and a third output terminal, the third inverting input terminal being electrically connected to the third output terminal, the third non-inverting input terminal being electrically connected to the second terminal, and the third output terminal being electrically connected to the voltage output terminal.

11. The voltage generation circuit according to claim 1, further comprising:
a diode having a first diode terminal and a second diode terminal, the first diode terminal being electrically connected to the second capacitive terminal, and the second diode terminal being electrically connected to the first output terminal.

12. The voltage generation circuit according to claim 11, further comprising:
a sixth resistor having an eleventh terminal and a twelfth terminal, the eleventh terminal being electrically connected to the second diode terminal, and the twelfth terminal being electrically connected to the first output terminal.

13. The voltage generation circuit according to claim 1, further comprising:
a transistor having a base terminal, a collector terminal, and an emitter terminal, the base terminal being electrically connected to the second terminal, and the collector terminal being electrically connected to the second capacitive terminal; and
a seventh resistor having a thirteenth terminal and a fourteenth terminal, the thirteenth terminal being electrically connected to the emitter terminal, and the fourteenth terminal being electrically connected to the first output terminal.

14. The voltage generation circuit according to claim 13, further comprising:
a fifth capacitor having a ninth capacitive terminal and a tenth capacitive terminal, the ninth capacitive terminal being electrically connected to the collector terminal and the second capacitive terminal, and the tenth capacitive terminal being electrically connected to the base terminal and the second terminal.

15. The voltage generation circuit according to claim 14, further comprising:
an eighth resistor having a fifteenth terminal and a sixteenth terminal, the fifteenth terminal being electrically connected to the second terminal, and the sixteenth terminal being electrically connected to the base terminal and the tenth capacitive terminal.

16. An audio output circuit comprising:
the voltage generation circuit according to claim 1; and
a fourth operational amplifier, wherein
the fourth operational amplifier has a first input terminal, a second input terminal, and a fourth output terminal,
an output voltage output by the voltage generation circuit is input to the first input terminal,
an audio input signal is input to the second input terminal, and
an audio output signal based on the audio input signal is output from the fourth output terminal.
